(19) United States
(12) Patent Application Publication
(10) Pub. No.: US 2014/0139817 A1
(43) Pub. Date: May 22, 2014

(54) SOLID-STATE IMAGE SENSOR AND RANGE FINDER USING THE SAME

(71) Applicant: Canon Kabushiki Kaisha, Tokyo (JP)

(72) Inventor: Daisuke Yamada, Cambridge, MA (US)

(73) Assignee: Canon Kabushiki Kaisha, Tokyo (JP)

(21) Appl. No.: 14/068,948

(22) Filed: Oct. 31, 2013

(30) Foreign Application Priority Data
Nov. 20, 2012 (JP) 2012-253961
Oct. 7, 2013 (JP) 2013-209805

(51) Int. Cl. G01C 3/08; H01L 27/146

(52) U.S. Cl. CPC G01C 3/08; H01L 27/14605
USPC 356/4.01; 250/208.1

(57) ABSTRACT

The invention provides a solid-state image sensor including a plurality of pixels, at least one pixel of the plurality of the pixels having a plurality of photoelectric conversion portions and a pupil-dividing member that causes light that passes through an exit pupil and is incident on a region defined by the member itself to be incident on the plurality of the photoelectric conversion portions, wherein potential profiles with respect to electric charge of the plurality of the photoelectric conversion portions change in a perpendicular line direction of the substrate, and wherein a distance between potential centroids in a section perpendicular to the perpendicular line of the plurality of the photoelectric conversion portions is longer on a back side that is a side opposite to a light incidence side than on the light incidence side.

### BACKGROUND OF THE INVENTION

1. Field of the Invention

The present invention relates to a solid-state image sensor, a range finder using the solid-state image sensor and imaging devices using the range finder, such as a digital still camera and a digital video camera.

2. Description of the Related Art

For a digital still camera or video camera, there has been proposed a solid-state image sensor using a ranging pixel having a ranging (focus-detecting) function for some or all of the pixels of the solid-state image sensor, so as to detect an object distance by a phase difference system (Japanese Patent No. 4027113). The ranging pixel is so constructed that a plurality of photoelectric conversion portions are provided to guide light fluxes having passed through different exit pupil regions of a camera lens to different photoelectric conversion portions. The photoelectric conversion portion has a function of converting light to an electric charge and storing the electric charge during a photographing (exposure).

Here, a plurality of ranging pixels are used to detect images (referred to as an image A and an image B, respectively) by light fluxes having passed through different regions of an exit pupil, thereby measuring an amount of deviation between the image A and the image B. An amount of defocus is calculated from this amount of deviation and a base length (space between different exit pupil regions) to detect a distance (focus position). At this time, the exit pupil surface of the camera lens and the surface of the photoelectric conversion portion reside substantially in a conjugate relation. Accordingly, an exit pupil region to pass through and light reception sensitivity are determined according to the position and size of the photoelectric conversion portion. That is, when the photoelectric conversion portion is made large, the passing exit pupil region becomes large, and the quantity of light received in the photoelectric conversion portion increases to heighten the sensitivity.

When photoelectric conversion portions of a ranging pixel having a plurality of photoelectric conversion portions are formed large, the proportion of the photoelectric conversion portions in the ranging pixel becomes large, and the distance between the photoelectric conversion portions gets closer. When the distance between the photoelectric conversion portions gets closer, an electric charge generated in one photoelectric conversion portion easily migrates to another photoelectric conversion portion (electronic crosstalk). An electric charge signal thereby mutually interferes between the photoelectric conversion portions in the ranging pixel, so that the electric charge signal is difficult to correspond to the exit pupil region through which light fluxes have passed. As a result, an error occurs in the amount of deviation between the image A and the image B and in the base length, and so ranging precision is liable to be deteriorated.

### SUMMARY OF THE INVENTION

The present invention has been made in view of the foregoing problems. According to the present invention, there is provided a solid-state image sensor comprising a plurality of pixels, at least one pixel of the plurality of the pixels having a plurality of photoelectric conversion portions and a pupil-dividing member that causes light that passes through an exit pupil and is incident on a region defined by the member itself to be incident on the plurality of the photoelectric conversion portions, wherein potential profiles (hereinafter also referred to as shape) with respect to electric charge of the plurality of the photoelectric conversion portions change in a perpendicular line direction of the substrate, and wherein a distance between potential centroids in a section perpendicular to the perpendicular line of the plurality of the photoelectric conversion portions is longer on a back side that is a side opposite to a light incidence side than on the light incidence side.

According to the present invention, the potential profiles of the plurality of the photoelectric conversion portions of the ranging pixel are formed as described above, so that a solid-state image sensor capable of conducting ranging with high sensitivity and high precision, and a range finder using the same can be realized.

Further features of the present invention will become apparent from the following description of exemplary embodiments with reference to the attached drawings.

### BRIEF DESCRIPTION OF THE DRAWINGS

FIG. 1 illustrates a range finder or imaging device using a solid-state image sensor according to the present invention.

FIG. 2 is a cross-sectional view illustrating one ranging pixel of a group of ranging pixels in the solid-state image sensor.

FIG. 3 illustrates the relation between a semiconductor substrate surface and an exit pupil surface of a camera lens.

FIG. 4 illustrates a graph explaining sensitivities of two photoelectric conversion portions with respect to angle of incidence of light incident on the pixel.

FIGS. 5A and 5B illustrate a state in which the shapes of the two photoelectric conversion portions change in a perpendicular line direction of a substrate.

FIG. 6 is a cross-sectional view illustrating a scattering portion formed in such a manner that light does not reach a barrier portion.

FIG. 7 is a cross-sectional view illustrating inclination of the shapes of the two photoelectric conversion portions in a depth direction.

FIGS. 8A, 8B, 8C and 8D illustrate a production process of the solid-state image sensor containing the pixel.

FIG. 9 illustrates other exemplary shapes of the photoelectric conversion portions which change in the perpendicular line direction of the substrate.

### DESCRIPTION OF THE EMBODIMENTS

Preferred embodiments of the present invention will now be described in detail in accordance with the accompanying drawings.

In the present invention, at least one pixel of a plurality of pixels formed in a solid-state image sensor is used as a ranging pixel having a plurality of photoelectric conversion portions formed in a substrate. Each of the plurality of the photoelectric conversion portions changes in potential profile with respect to electric charge in a perpendicular line direction of the substrate, and a distance between potential centroids in a section perpendicular to the perpendicular line of the plurality of the photoelectric conversion portions is longer on a back side that is a side opposite to a light incidence side than on the light incidence side. And, a distance between mutually opposing inside contours of the potential profiles of the plurality of the photoelectric conversion portions in a direction perpendicular to the perpendicular line may be longer on a back side that is a side opposite to a light incidence side than on the light incidence side. Since the potential of the photoelectric conversion portion is lower than a surrounding potential, the potential profile is defined by a boundary thereof. In addition, the potential centroid in the section perpendicular to the perpendicular line is defined as a position where, with the centroid as a center, a sumproduct of a distance from the centroid and a potential depth at that position balances in both sides in the perpendicular section. The present invention is intended to inhibit the mutual interference of the accumulated electric charge between the photoelectric conversion portions. It is better for this to arrange regions where the accumulated electric charge is relatively dense as separate as possible in the back side. Therefore, in the present invention, at least one of the distance between the contours in the direction perpendicular to the perpendicular line and the distance between the potential centroids is controlled so as to become longer on the back side that is a side opposite to the light incidence side than on the light incidence side. In an embodiment which will be described subsequently, both distances between the contours and between the centroids become gradually longer toward the back side from the light incidence side. However, the present invention is not limited to this mode. Examples of other modes include such a mode that the distance between the contours in the direction perpendicular to the perpendicular line does not very change in the perpendicular line direction of the substrate, while the distance between the potential centroids becomes longer toward the back side. Signal separation performance in each photoelectric conversion portion is improved by the above-described construction to improve distance measurement precision. In addition, since the plurality of the photoelectric conversion portions may not be so separated on the light incidence side, a lot of incident light can be received to prevent the reduction of sensitivity.

The solid-state image sensor according to an embodiment of the present invention and a range finder using the same will hereinafter be described with references to the attached drawings. In that embodiment, a digital camera is described as an example of imaging devices equipped with the range finder. However, the present invention is not limited thereto. In addition, those having the same function are given the same reference signs in all the drawings, and their repeated descriptions are omitted or simplified.

### Embodiment

An embodiment relating to a solid-state image sensor to which the present invention is applied, a range finder equipped with this sensor, and imaging devices containing this detector, such as a camera will be described.

### Construction of Range Finder

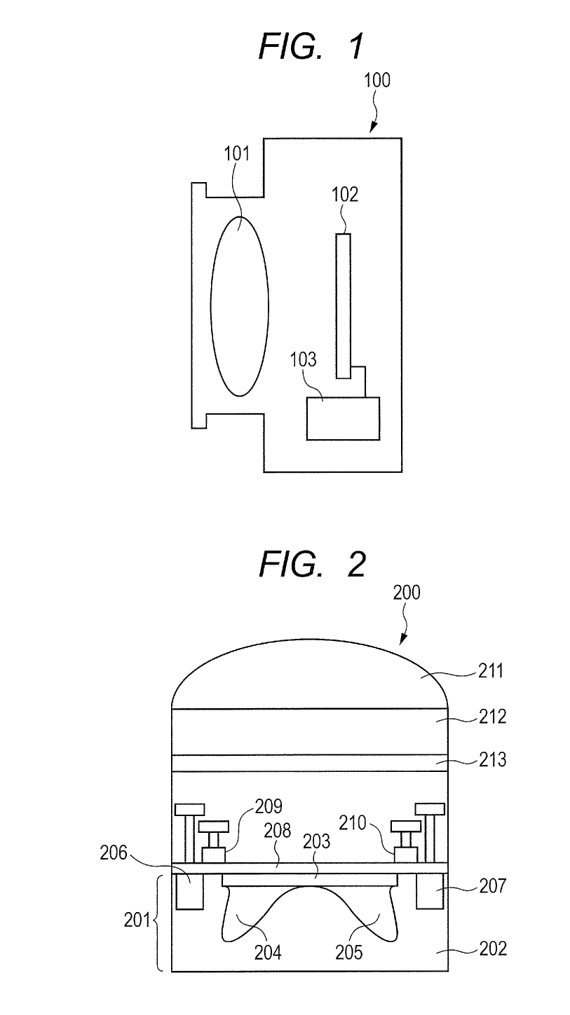

FIG. 1 illustrates a range finder 100 according to the embodiment. The range finder 100 is constituted of a camera lens 101, a solid-state image sensor 102 and an operation unit 103. In this range finder, in order to obtain distance information of an object, an image of the object is formed on the solid-state image sensor 102 by the camera lens 101 that is an optical system for forming the image of the object on the solid-state image sensor, thereby obtaining an image A and an image B of the object with a group of ranging pixels arranged in the solid-state image sensor 102. The information of the images A and B thus obtained is transferred to the operation unit 103 to calculate distance information of the object from the relation between the amount of deviation between the image A and the image B and a base length. That is, the distance information of the object is obtained with a plurality of output signals from a plurality of photoelectric conversion portions in the ranging pixels. When an AF mechanism, a display device for displaying the image obtained by the solid-state image sensor, a shutter mechanism and a memory for storing constants, variables and various programs for operation of a system control unit are provided in addition to the above-described components, the detector illustrated in FIG. 1 can also be recognized as an imaging device such as a camera. In such a camera, an object image formed by the optical system can also be obtained by the solid-state image sensor 102 of the range finder.

### Construction of Solid-State Image Sensor

FIG. 2 illustrates a ranging pixel 200 that is a part of the group of the ranging pixels arranged in the solid-state image sensor. The pixel 200 is constituted of a P-type well 202 composed of a P-type in a semiconductor substrate 201, a surface P⁺ layer 203, an N-type first photoelectric conversion portion 204 and an N-type second photoelectric conversion portion 205, and floating diffusion portions (hereinafter referred to as FD portions) 206 and 207. In addition, a gate insulator film 208, and gate electrodes 209 and 210 are arranged on the side of the surface P⁺ layer of the semiconductor substrate 201. Light incident on the pixel 200 is guided to the first photoelectric conversion portion 204 and the second photoelectric conversion portion 205 through a condenser member 211 such as a microlens, a color filter 212 and a flattened layer 213. The light incident on the photoelectric conversion portions 204 and 205 is converted to electrons and stored in the photoelectric conversion portions 204 and 205. Thereafter, a signal is applied to the gate electrodes 209 and 210 to transfer the electrode to the FD portions 206 and 207, thereby detecting respective electric charge quantities as electric signals.

### Acquisition of Distance Information

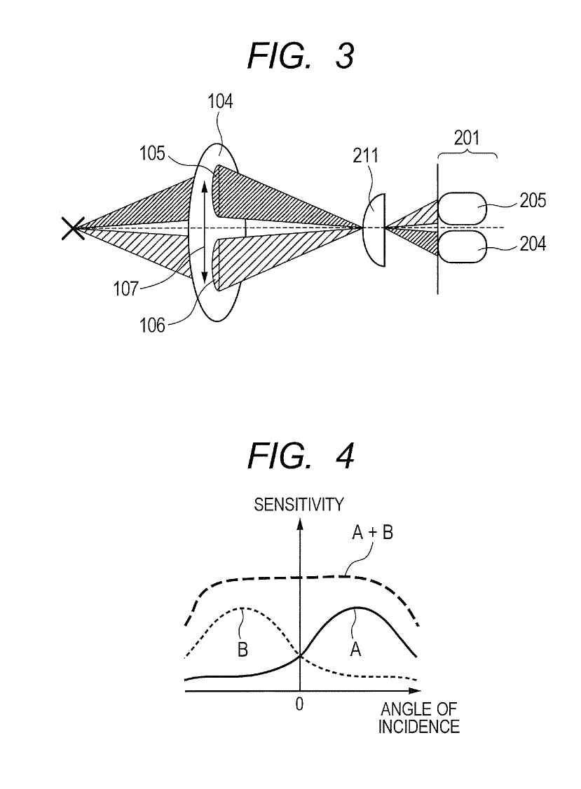

Here, the surface of the semiconductor substrate 201 and the surface of an exit pupil 104 of the camera lens reside substantially in a conjugate relation. Accordingly, the first photoelectric conversion portion 204 and the second photoelectric conversion portion 205 of the ranging pixel respectively receive light fluxes having passed through different exit pupil regions (first region 105 and second region 106) as illustrated in FIG. 3. At this time, the light fluxes having passed through the first region 105 and the second region 106 are respectively incident on the pixel 200 at different angles. Thus, the sensitivities of the first photoelectric conversion portion 204 and the second photoelectric conversion portion 205 with respect to the angles of incidence of the light incident on the pixel 200 have peaks on a plus side (A) and a minus side (B), respectively, as illustrated in FIG. 4. The object distance can be detected by a publicly known method using the amount of deviation between the image A and the image B which are respectively formed from the plurality of the first photoelectric conversion portions 204 and the plurality of the second photoelectric conversion portions 205 having these sensitivities.

Incidentally, the pixel in the present invention has a single pupil-dividing member. That is, different pupils have their corresponding different pupil-dividing members. The pupil-dividing member has a function of causing light that passes through the exit pupil 104 and is incident on a region defined by the pupil-dividing member to be incident on the photoelectric conversion portion 204 or 205. For example, the pupil-dividing member may be such a condenser member 211 as described above or an optical waveguide formed by a core member and a cladding member.

### Acquisition of Imaging Information

In order to obtain an imaging image using the ranging pixel, it is only necessary to add signals of all the photoelectric conversion portions (the first photoelectric conversion portion 204 and the second photoelectric conversion portion 205) present in the pixel. An imaging signal (‘A+B’ in FIG. 4) that has passed through the whole region of the exit pupil 104 is thereby obtained. Accordingly, object images can be obtained at all the photoelectric conversion portions by using the ranging pixel like an ordinary solid-state image sensor.

### Shape of Photoelectric Conversion Portion

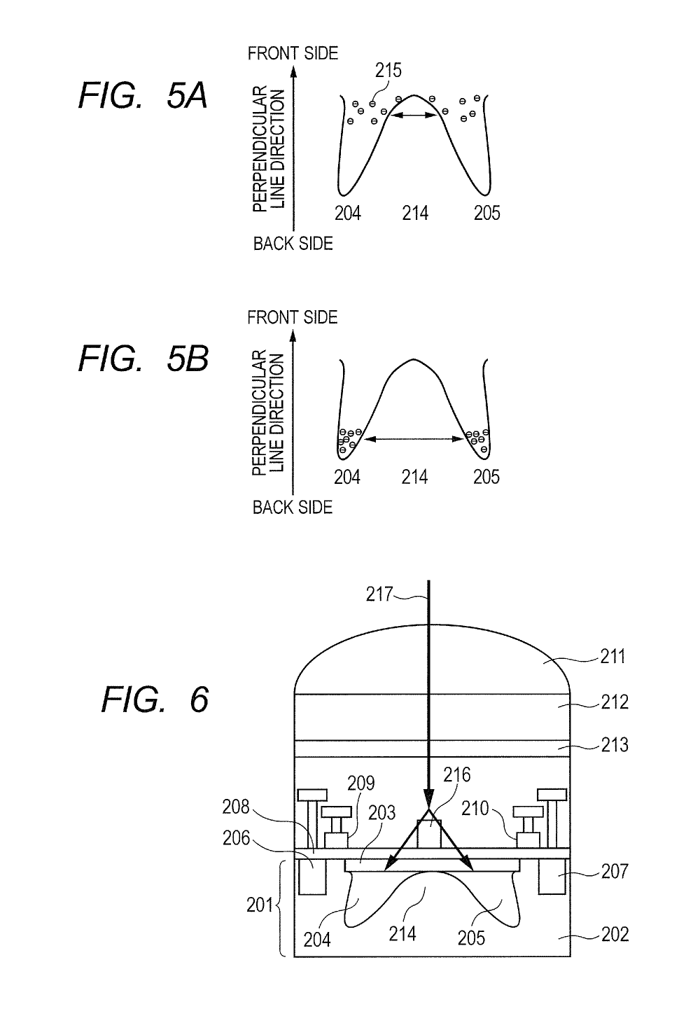

The photoelectric conversion portions according to the embodiment will be described with reference to FIGS. 5A and 5B. The photoelectric conversion portions 204 and 205 change in shape (potential profile) in a perpendicular line direction of the semiconductor substrate 201. In addition, a distance between potential centroids in a section perpendicular to the perpendicular line of the first photoelectric conversion portion 204 and the second photoelectric conversion portion 205 is shorter toward a front side that is a light incidence side and longer toward a back side that is a side opposite to the front side. Since the potential of the photoelectric conversion portion is lower than a surrounding potential as described above, the potential profile of the photoelectric conversion portion can be defined. The sensitivity of the pixel 200 can be heightened by such construction, and so ranging precision in ranging using the pixel 200 becomes high. The reason for it will hereinafter be described.

Light incident on the ranging pixel is converted to electrons 215 at a light incidence side surface of the photoelectric conversion portion (FIG. 5A). For example, when the wavelength of the incident light is 500 nm and the photoelectric conversion portion is formed with silicon, most of the light is converted to electrons at a depth up to 500 nm from the light incidence side surface. The distance until the light is converted to the electrons and the intensity of the light is lowered to 1/e is determined by the wavelength of the light and the material of the photoelectric conversion portion. The electrons 215 generated in the photoelectric conversion portion migrate to the back sides in the photoelectric conversion portion. The electrons 215 having migrated are continuously stored on the back side until photographing (exposure) is completed (FIG. 5B). However, the potential on the back side of the photoelectric conversion portion is lower than that on the front side. At this time, the time when the electrons are stored on the back side is sufficiently long compared with a relaxation life in which the light is converted to the electrons at the light incidence side surface of the photoelectric conversion portion and stays. Therefore, the degree of electronic crosstalk is determined by the structure of the back side of the photoelectric conversion portion where the electrons are stored. In sum, the generation of the electrons occurs at the light incidence side surface of the photoelectric conversion portion, and the degree of the electronic crosstalk is determined by the shape (potential profile) of the back side of the photoelectric conversion portion.

On the other hand, a portion between the first photoelectric conversion portion and the second photoelectric conversion portion is formed of a P-type semiconductor to form a barrier portion 214 with a higher potential than the photoelectric conversion portions. Since this barrier portion 214 does not have a function of storing the electrons, this portion does not have sensitivity even when light reaches the barrier portion 214 or becomes a main cause of the electronic crosstalk noise. Accordingly, when the incident light is condensed on the photoelectric conversion portions 204 and 205 without reaching the barrier portion 214, the sensitivity becomes high, and the noise is lowered. In the solid-state image sensor according to this embodiment, the distance between the potential centroids of the first photoelectric conversion portion 204 and the second photoelectric conversion portion 205 in the direction perpendicular to the perpendicular line was made short on the light incidence side to form the barrier portion thin in order to cause the incident light to reach the photoelectric conversion portions. The barrier portion 214 is formed thin, whereby the area proportion of the photoelectric conversion portions 204 and 205 in the pixel when viewed from the light incidence side can be made large to improve the sensitivity.

In addition to this, the photoelectric conversion portions are formed in such a manner that the barrier portion becomes thick by making long the distance between the potential centroids of the first photoelectric conversion portion 204 and the second photoelectric conversion portion 205 on the back side as described above. The mutual interference (electronic crosstalk) of the electrons accumulated in the photoelectric conversion portions between the photoelectric conversion portions thereby becomes small, and so signal separation performance in each photoelectric conversion portion is improved. As a result, light separation characteristics are improved to improve the ranging precision.

Here, as illustrated in FIG. 6, a scattering portion 216 formed of a medium having a refractive index lower than that of a surrounding medium is formed on the light incidence side of the barrier portion 214 in such a manner that as little light 217 as possible reaches the barrier portion 214. This structure bends the direction of the light incident on the barrier portion at the scattering portion 216, so that the light propagates to the side of the photoelectric conversion portion. At this time, the light having reached the photoelectric conversion portion propagates to an end side of the pixel in the photoelectric conversion portion. Accordingly, when the photoelectric conversion portions according to this embodiment are used, a direction of a line linking the potential centroids and extending in a depth direction of the photoelectric conversion portion or a direction of the opposing inside contours of the potential profiles is almost the same as the propagating direction of the light, so that the light can be efficiently converted to electrons. The sensitivity of the solid-state image sensor can be thereby heightened.

In addition, peak positions of the sensitivities of the first photoelectric conversion portion 204 and the second photoelectric conversion portion 205 of the ranging pixel with respect to the angle of incidence are each designed so as to be at between 5 degrees and 20 degrees in terms of absolute value as illustrated in FIG. 4. The peak position of the sensitivity is designed so as to be on a plus side or minus side apart from zero as described above, whereby the amount of deviation between the image A and the image B can be suitably measured to improve the ranging precision. In such a case, light incident at an angle of incidence of from 5 degrees to 20 degrees to the perpendicular line propagates at an angle of from 1.0 degree to 6.0 degrees according to the Snell's law. Here, the photoelectric conversion portions were formed of silicon, and the wavelength of the light was set to be in a visible region. At this time, the refractive index of silicon is 3.5 or more and 5.0 or less.

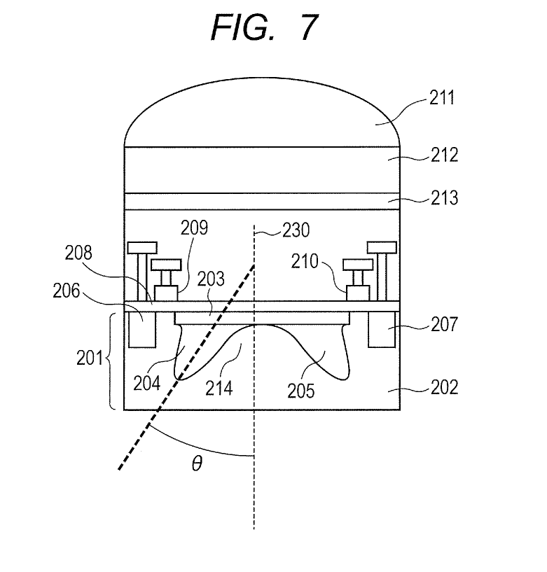

As illustrated in FIG. 7, the opposing inside contours of the potential profiles of the first and second photoelectric conversion portions 204 and 205 in a perpendicular line direction 230 or the line linking the potential centroids in a direction perpendicular to the perpendicular line direction 230 is designed in the following manner in accordance with the propagating direction of the incident light. That is, it is designed in such a manner that an inclination θ from the perpendicular line direction 230 of the semiconductor substrate 201 is 1.0 degree or more and 6.0 degrees or less. The inclination in a depth direction of the shape of the photoelectric conversion portion thereby substantially conforms to the propagating direction of the light, and so the incident light can be efficiently converted to electrons in the photoelectric conversion portion, whereby the sensitivity of the solid-state image sensor can be heightened.

In FIG. 7, the inclination of the line linking the potential centroids and extending to the depth direction of the photoelectric conversion portion has been illustrated so as to be a straight line. However, the inclination may not be always the straight line, and it may also be formed so as to have a curvature. In addition, since the refractive index of silicon is from 3.9 to 4.3 at a wavelength of from 500 nm to 600 nm at which spectral luminous efficiency is high, the shape of the photoelectric conversion portion is desirably inclined at an angle of from 1.3 degrees to 4.6 degrees with respect to the perpendicular line direction 230 of the semiconductor substrate 201. When the photoelectric conversion portion has a sensitivity peak between 10 degrees and 15 degrees, the sensitivity becomes high, and so the ranging precision also becomes high. In this case, the inclination of the line linking the centroids and extending in the depth direction of the photoelectric conversion portion or of the opposing inside contours of the potential profiles is desirably between 2.5 degrees and 3.5 degrees with respect to the perpendicular line direction 230 of the semiconductor substrate 201.

Production Process of Solid-State Image Sensor

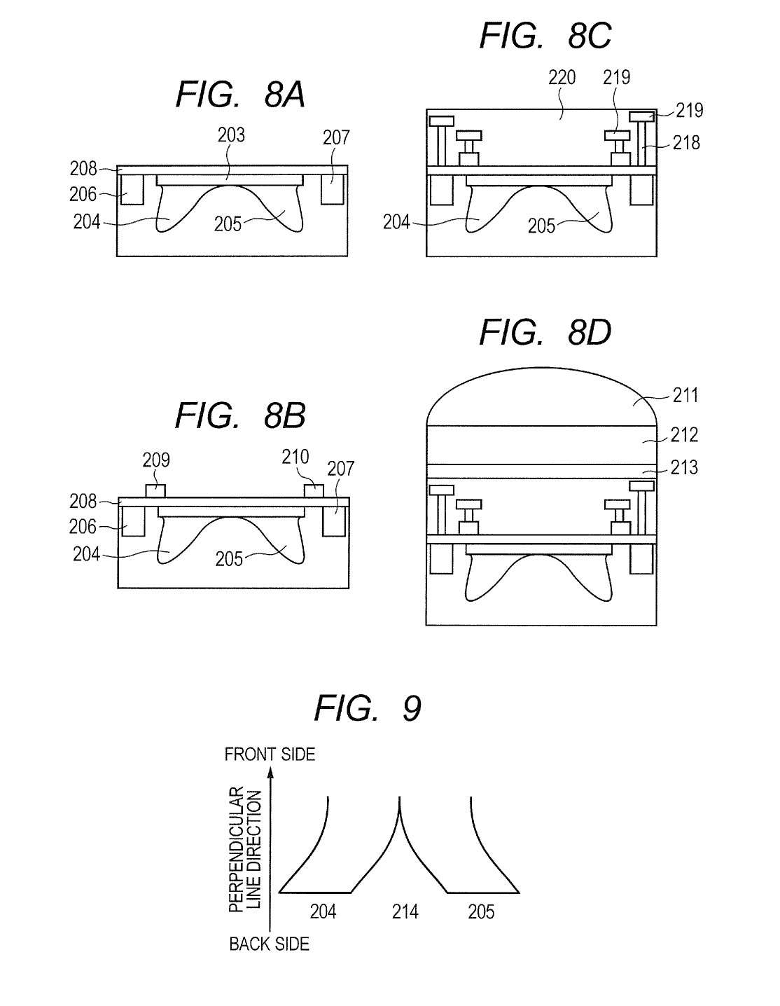

A production process of a solid-state image sensor including the pixel 200 according to this embodiment will now be described with reference to FIGS. 8A to 8D. A gate insulator film 208 is first formed on a surface of a silicon semiconductor substrate 201 by thermal oxidation. A photoresist is then formed as a resist mask at a predetermined position for forming photoelectric conversion portions 204 and 205 with an inclined shape in the semiconductor substrate 201 followed by conducting impurity ion implantation from an oblique direction with respect to the semiconductor substrate 201. The photoelectric conversion portions according to this embodiment can be thereby formed. Thereafter, the resist mask is removed by, for example, asking.

FD portions 206 and 207 and a diffusion portion (not illustrated) are then formed by the same ion implantation method (FIG. 8A). In addition, a polysilicon film is formed for forming gate electrodes for transferring electrons generated in the photoelectric conversion portions 204 and 205. Thereafter, the polysilicon is etched to a predetermined pattern by means of a photolithographic process to form the gate electrodes 209 and 210 (FIG. 8B). Thereafter, an interlayer insulating film 220 composed of, for example, BPSC (boron phosphorus silicon glass) is formed on the semiconductor substrate 201 and the gate electrodes followed by flattening by a CMP process.

A connection hole such as a contact hole 218 is then formed in the interlayer insulating film for electrical connection to electrically connect with another metal wiring. Likewise, a wiring 219 is formed and covered with the interlayer insulating film 220 (FIG. 8C). Thereafter, a flattened layer 213, a color filter 212 and a microlens 211 are formed as needed (FIG. 8D).

Incidentally, in this embodiment, the photoelectric conversion portions 204 and 205 have been formed by an oblique ion implantation process. However, the process is not limited thereto. For example, an ion implantation process may be conducted several times according to an impurity concentration and a depth direction of the substrate to form the photoelectric conversion portions. In this embodiment, description has been given taking a CMOS solid-state image sensor of a front-side illumination type as an example. However, the solid-state image sensor is not limited to the front-side illumination type. Even when the present invention is applied to a back-side illumination type in which the positions of the metal wiring portion and the photoelectric conversion portions are reversed, the same effect is achieved. In this embodiment, the photoelectric conversion portions have been formed with the N-type semiconductor. However, they may also be formed with a P-type semiconductor. In this case, a hole is generated as an electric charge by light.

In addition, the shape of the photoelectric conversion portions according to the present invention is not limited to the downward tapering convex form as illustrated in FIGS. 5A and 5B. When the shapes (potential profiles) of the photoelectric conversion portions change in the perpendicular line direction of the substrate, and the barrier portion 214 is formed so as to become gradually thicker toward the back side from the light incidence side as illustrated in FIG. 9, the sensitivity becomes high, and the ranging precision is improved. In the construction illustrated in FIG. 9, the width of the potential profile of the photoelectric conversion portion in the direction perpendicular to the perpendicular line direction of the substrate is almost constant, and the inclination of the line linking the centroids and extending to the depth direction or the inclination of the opposing inside contours of the potential profiles is as described above. In this embodiment, the case where a pixel has two photoelectric conversion portions has been described. However, the number of the photoelectric conversion portions is not limited to two and can be any plural number (for example, an even number such as 2 or 4).

Although the favorable embodiment of the present invention has been described above, the present invention is not to this embodiment, and various modifications and changes may be made within the gist of the present invention. The above-described solid-state image sensor according to the present invention can be used in imaging devices such as a digital camera requiring a range finder, to say nothing of the range finder. At that time, it is only necessary to suitably position the solid-state image sensor with respect to an optical system which forms an image of an object according to its construction.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2012-253961, filed Nov. 20, 2012, and No. 2013-209805, filed Oct. 7, 2013 which are hereby incorporated by reference herein in their entirety.

What is claimed is:

1. A solid-state image sensor comprising a plurality of pixels,
at least one pixel of the plurality of the pixels having:
a plurality of photoelectric conversion portions and
a pupil-dividing member that causes light that passes through an exit pupil and is incident on a region defined by the member itself to be incident on the plurality of the photoelectric conversion portions,
wherein potential profiles with respect to electric charge of the plurality of the photoelectric conversion portions change in a perpendicular line direction of the substrate, and
wherein a distance between potential centroids in a section perpendicular to the perpendicular line of the plurality of the photoelectric conversion portions is longer on a back side that is a side opposite to a light incidence side than on the light incidence side.

2. The solid-state image sensor according to claim 1, wherein a distance between mutually opposing inside contours of the potential profiles of the plurality of the photoelectric conversion portions in the direction perpendicular to the perpendicular line is longer on the back side that is a side opposite to the light incidence side than on the light incidence side.

3. The solid-state image sensor according to claim 1, wherein potentials of the plurality of the photoelectric conversion portions are lower than a surrounding potential.

4. The solid-state image sensor according to claim 1, wherein a line linking potential centroids of the plurality of the photoelectric conversion portions in a direction perpendicular to the perpendicular line or opposing inside contours of the potential profiles of the plurality of the photoelectric conversion portions has an inclination of 1.0 degree or more and 6.0 degrees or less from the perpendicular line direction.

5. The solid-state image sensor according to claim 4, wherein the line linking potential centroids of the plurality of the photoelectric conversion portions in a direction perpendicular to the perpendicular line or the opposing inside contours of the potential profiles of the plurality of the photoelectric conversion portions has an inclination of 1.3 degree or more and 4.6 degrees or less from the perpendicular line direction.

6. The solid-state image sensor according to claim 5, wherein the line linking potential centroids of the plurality of the photoelectric conversion portions in a direction perpendicular to the perpendicular line or the opposing inside contours of the potential profiles of the plurality of the photoelectric conversion portions has an inclination of 2.5 degree or more and 3.5 degrees or less from the perpendicular line direction.

7. The solid-state image sensor according to claim 1, wherein a scattering portion formed of a medium having a refractive index lower than that of a surrounding medium is formed on the light incidence side of a portion between the plurality of the photoelectric conversion portions.

8. A range finder comprising
the solid-state image sensor according to claim 1, and
an operation unit for obtaining distance information of an object by using a plurality of output signals from the plurality of the photoelectric conversion portions of the pixel having the plurality of the photoelectric conversion portions.

9. An imaging device comprising
the range finder according to claim 8, and
an optical system for forming an image of an object on the solid-state image sensor.
